(19) United States
(12) Patent Application Publication
(10) Pub. No.: US 2025/0323610 A1
(43) Pub. Date: Oct. 16, 2025

(54) POWER AMPLIFYING CIRCUIT

(71) Applicant: Murata Manufacturing Co., Ltd., Nagaokakyo-shi (JP)

(72) Inventor: Yuri HONDA, Nagaokakyo-shi (JP)

(21) Appl. No.: 19/248,757

(22) Filed: Jun. 25, 2025

Related U.S. Application Data
(63) Continuation of application No. PCT/JP2023/047344, filed on Dec. 28, 2023.

(30) Foreign Application Priority Data
Jan. 4, 2023 (JP) 2023-000310

(51) Int. Cl. H03F 3/24; H03F 1/56; H03F 3/45; H03F 3/72

(52) U.S. Cl. CPC H03F 3/245; H03F 1/565; H03F 3/4508; H03F 3/72; H03F 2203/7209

(57) ABSTRACT

A power amplifying circuit that can set load impedances of amplifiers at optimal locations for a wide band is provided. The power amplifying circuit includes a differential amplifier having a first amplifier and a second amplifier, a first output terminal, and a second output terminal. By turning each switch on or off, a signal of a desired frequency is outputted from the first output terminal or the second output terminal. Inductors are provided in which turning directions of currents flowing therethrough are opposite to each other, and this causes magnetic coupling to weaken. By weakening this magnetic coupling, the size of a spiral of the impedance on the Smith chart is reduced. This enables the suppression of variation in the impedance with respect to the frequency. In a wide band operating frequency, a constant load impedance is realized using a series circuit made up of a switch and a capacitor.

### CROSS REFERENCE TO RELATED APPLICATION

This is a continuation of International Application No. PCT/JP2023/047344 filed on Dec. 28, 2023 which claims priority from Japanese Patent Application No. 2023-000310 filed on Jan. 4, 2023. The contents of these applications are incorporated herein by reference in their entireties.

### BACKGROUND OF THE DISCLOSURE

### Field of the Disclosure

The present disclosure relates to power amplifying circuits.

### Description of the Related Art

In some cases, a power amplifying circuit employs a two-stage configuration made up of a driver stage amplifier and a power stage amplifier (for example, U.S. Pat. No. 10,411,662). In a power amplifying circuit described in U.S. Pat. No. 10,411,662, in a 2G mode, a load impedance suited to the 2G mode can be set by switching a switch. Further, in a 3G mode, a load impedance suited to the 3G mode can be set.

### BRIEF SUMMARY OF THE DISCLOSURE

According to the technique described in U.S. Pat. No. 10,411,662 described above, it becomes possible to set an appropriate load impedance for each mode. However, when attention is directed to a specific mode, setting an appropriate load impedance for a wider frequency band becomes challenging in that mode, and this poses a problem.

The present disclosure is made in view of the above, and a possible benefit thereof is to provide a power amplifying circuit that can set load impedances of amplifiers at optimal locations for a wide band.

In order to resolve the issues described above and achieve the possible benefit, a power amplifying circuit according to a certain aspect of the present disclosure is a power amplifying circuit including a differential amplifier that includes a first amplifier and a second amplifier and output terminals that include a first output terminal and a second output terminal, the power amplifying circuit including: a first inductor; a second inductor that is mutually coupled with the first inductor; a third inductor that is mutually coupled with the first inductor, power for the differential amplifier being supplied to an intermediate point of the first inductor, one end portion of the second inductor being connected to one end portion of the third inductor; a first capacitor, one end portion of the first capacitor being connected to another end portion of the second inductor; a first switch that is provided between the first output terminal and a connecting point of the one end portion of the second inductor and the one end portion of the third inductor; a second switch that is provided between another end portion of the third inductor and the second output terminal; a third switch, one end portion of the third switch being connected between the third inductor and the second switch; and a second capacitor that is connected between another end portion of the third switch and a reference potential, wherein another end portion of the first capacitor is connected to the reference potential, and by controlling the first switch, the second switch, and the third switch to be on or off, a signal of a desired frequency is outputted from the first output terminal or the second output terminal.

A power amplifying circuit according to another aspect of the present disclosure is a power amplifying circuit including a differential amplifier that includes a first amplifier and a second amplifier and output terminals that include a first output terminal and a second output terminal, the power amplifying circuit including: a first inductor; a second inductor that is mutually coupled with the first inductor; a third inductor that is mutually coupled with the first inductor, power for the differential amplifier being supplied to an intermediate point of the first inductor, one end portion of the second inductor being connected to one end portion of the third inductor; a first capacitor, one end portion of the first capacitor being connected to another end portion of the second inductor; a first switch that is provided between the first output terminal and a connecting point of the one end portion of the second inductor and the one end portion of the third inductor; a second switch that is provided between another end portion of the third inductor and the second output terminal; and a fifth inductor, one end portion of the fifth inductor being connected to a connecting point of the second inductor and the first capacitor, wherein another end portion of the first capacitor is connected to a reference potential, another end portion of the fifth inductor is connected to the reference potential, the fifth inductor is mutually coupled with the first inductor, a turning direction of a current flowing through the first inductor is opposite a turning direction of a current flowing through the fifth inductor, and by controlling the first switch and the second switch to be on or off, a signal of a desired frequency is outputted from the first output terminal or the second output terminal.

A power amplifying circuit according to another aspect of the present disclosure is a power amplifying circuit including a differential amplifier that includes a first amplifier and a second amplifier and output terminals that include a first output terminal and a second output terminal, the power amplifying circuit including: a first inductor; a second inductor that is mutually coupled with the first inductor; a third inductor that is mutually coupled with the first inductor, power for the differential amplifier being supplied to an intermediate point of the first inductor, one end portion of the second inductor being connected to one end portion of the third inductor; a first switch that is provided between the first output terminal and a connecting point of the one end portion of the second inductor and the one end portion of the third inductor; a second switch that is provided between another end portion of the third inductor and the second output terminal; a second capacitor, one end portion of the second capacitor being connected between the third inductor and the second switch, another end portion of the second capacitor being connected to a reference potential; a fourth capacitor that is provided between the another end portion of the third inductor and the one end portion of the second capacitor; and a fifth capacitor that is provided between the first switch and the connecting point of the one end portion of the second inductor and the one end portion of the third inductor, wherein another end portion of the second inductor is connected to the reference potential, and by controlling the first switch and the second switch to be on or off, a signal of a desired frequency is outputted from the first output terminal or the second output terminal.

According to the power amplifying circuit according to the present disclosure, it becomes possible to set the load impedances of the amplifiers at optimal locations for a wide band.

### BRIEF DESCRIPTION OF THE SEVERAL VIEWS OF THE DRAWINGS

FIG. 1 is a diagram illustrating one example of a power amplifying circuit of a comparative example.

FIG. 2 is a diagram illustrating a power amplifying circuit according to a first embodiment.

FIG. 3 is a diagram illustrating the operating state of each switch.

FIG. 4 is a Smith chart illustrating load impedances of amplifiers of FIG. 2.

FIG. 5 is a diagram illustrating one example of an equivalent circuit of a typical balun.

FIG. 6 is a Smith chart illustrating the impedance seen from a primary side termination resistor when a circuit of FIG. 5 is used as a matching circuit of a power amplifier.

FIG. 7 is a Smith chart illustrating the impedance seen from the primary side termination resistor when the circuit of FIG. 5 is used as the matching circuit of the power amplifier.

FIG. 8 is a Smith chart illustrating the impedance seen from the primary side termination resistor when the circuit of FIG. 5 is used as the matching circuit of the power amplifier.

FIG. 9 is a Smith chart illustrating the impedance seen from each amplifier in FIG. 2 toward an output side.

FIG. 10 is a diagram illustrating a power amplifying circuit according to a second embodiment.

FIG. 11 is a diagram illustrating a power amplifying circuit according to a third embodiment.

FIG. 12 is a Smith chart illustrating the impedance seen from each amplifier in FIG. 11 toward an output side.

FIG. 13 is a diagram illustrating a power amplifying circuit according to a fourth embodiment.

FIG. 14 is a diagram to illustrate how a circuit appears at even-order harmonic waves of a harmonic processing circuit of the power amplifying circuit according to the fourth embodiment.

FIG. 15 is a diagram to illustrate how the circuit appears at a fundamental wave and odd-order harmonic waves of the harmonic processing circuit of the power amplifying circuit according to the fourth embodiment.

FIG. 16 is a diagram illustrating a power amplifying circuit according to a fifth embodiment.

FIG. 17 is a diagram illustrating an equivalent circuit of the power amplifying circuit illustrated in FIG. 16 at a fundamental wave frequency.

FIG. 18 is a diagram illustrating a power amplifying circuit according to a sixth embodiment.

FIG. 19 is a diagram illustrating a power amplifying circuit according to a seventh embodiment.

FIG. 20 is a diagram illustrating a power amplifying circuit according to an eighth embodiment.

FIG. 21 is a diagram illustrating a power amplifying circuit according to a ninth embodiment.

### DETAILED DESCRIPTION OF THE DISCLOSURE

Hereinafter, embodiments of the present disclosure will be described in detail on the basis of the drawings. In the description of each of the following embodiments, constituent elements identical or equivalent to those of another embodiment are denoted by the same reference characters, and descriptions thereof are simplified or omitted. The present disclosure is not limited by each embodiment. Further, constituent elements of each embodiment include those that can be easily conceived and replaced by a person skilled in the art, and those that are substantially identical thereto. Note that the constituent elements described below can be combined if appropriate. Further, the constituent elements can be omitted, replaced, or modified so long as they do not depart from the scope of the present disclosure.

First, to facilitate understanding of embodiments, a comparative example is described.

### Comparative Example

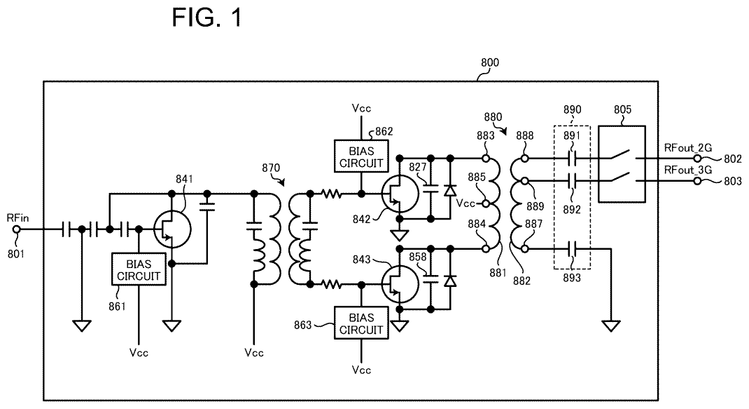

FIG. 1 is a diagram illustrating one example of a power amplifying circuit of a comparative example. FIG. 1 is a diagram illustrating a power amplifying module disclosed in U.S. Pat. No. 10,411,662. The power amplifying circuit illustrated in FIG. 1 employs a two-stage configuration made up of a driver stage amplifier and a power stage amplifier.

In FIG. 1, a power amplifying module 800 includes an amplifier 841, an amplifier 842, and an amplifier 843. The amplifier 841 corresponds to a driver stage. The amplifier 842 and the amplifier 843 correspond to a differential power stage. The power amplifying module 800 receives, as input, a signal RFin that is inputted to an input terminal 801. The power amplifying module 800 outputs a signal of a second-generation mobile communication system, which is a 2nd Generation (2G) signal RFout_2G, and a signal of a third-generation mobile communication system, which is a 3rd Generation (3G) signal RFout_3G.

An output of a bias circuit 861 is applied to a gate terminal of the amplifier 841. An output of a bias circuit 862 is applied to a gate terminal of the amplifier 842. An output of a bias circuit 863 is applied to a gate terminal of the amplifier 843.

An output of the amplifier 841, which corresponds to the driver stage, is inputted to the amplifier 842 and the amplifier 843, which correspond to the differential power stage, via a transformer 870. A capacitor 827 is connected to an output of the amplifier 842. A capacitor 858 is connected to an output of the amplifier 843.

A balun made up of the transformer 880 is connected to the output sides of the amplifier 842 and the amplifier 843. The transformer 880 includes an inductor 881 that is a primary winding and an inductor 882 that is a secondary winding. The inductor 881 and the inductor 882 are magnetically coupled to each other.

A first terminal 883 of the inductor 881 is connected to an output port of the amplifier 842. A second terminal 884 of the inductor 881 is connected to an output port of the amplifier 843. An intermediate tap 885 of the inductor 881 is connected to a power supply VCC.

A phase compensation circuit 890 is connected in series to the output side of the inductor 882. The phase compensation circuit 890 includes capacitors 891, 892, and 893. A switch 805 is connected to the output side of the phase compensation circuit 890.

A first terminal 888 of the inductor 882 is connected to an output terminal 802 via the capacitor 891 and the switch 805. The output terminal 802 is a terminal that outputs a 2G signal RFout_2G, which is a signal of the second-generation mobile communication system. A second terminal 889 of the inductor 882 is connected to an output terminal 803 via the capacitor 892 and the switch 805. The output terminal 803 is a terminal that outputs a 3G signal RFout_3G, which is a signal of the third-generation mobile communication system. A third terminal 887 of the inductor 882 is connected to a reference potential via the capacitor 893. Hereinafter, the operation of outputting the 2G signal RFout_2G is referred to as 2G mode. Further, the operation of outputting the 3G signal RFout_3G is referred to as 3G mode.

Here, the ratio between the number of turns of the inductor 881 and the number of turns of the inductor 882 at the time of outputting the 2G signal RFout_2G from the output terminal 802 is greater than the ratio between the number of turns of the inductor 881 and the number of turns of the inductor 882 at the time of outputting the 3G signal RFout_3G from the output terminal 803. This allows the load impedances of the amplifiers 842 and 843 in the 2G mode to be lower than the load impedances of the amplifiers 842 and 843 in the 3G mode.

By switching the switch 890, in the 2G mode, the load impedances suited to the 2G mode can be set. Further, in the 3G mode, the load impedances suited to the 3G mode can be set. As described above, in the power amplifying circuit of the comparative example, the 2G mode or the 3G mode is realized by turning the switch on or off. However, when attention is directed to a specific mode, setting an appropriate load impedance for a wider frequency band becomes challenging in that mode. The frequency band for the signal in the 3G mode is, for example, from 663 MHz to 915 MHz in a low band. When matching is considered in this frequency band, it is challenging to set the load impedances of the amplifiers 842 and 843 at optimal locations for a wide band.

### First Embodiment

Next, an embodiment is described.

### Configuration

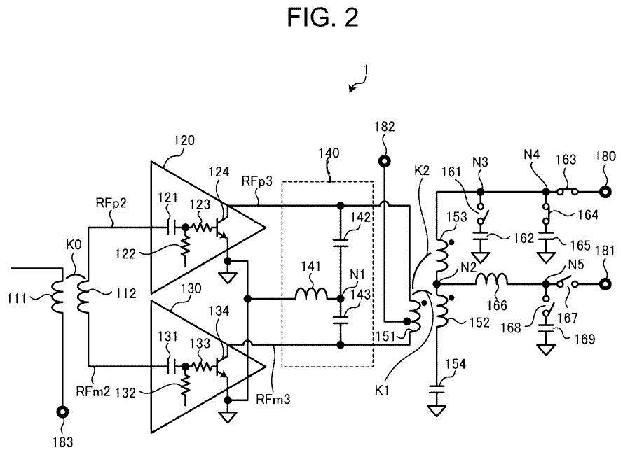

FIG. 2 is a diagram illustrating a power amplifying circuit 1 according to the first embodiment. In FIG. 2, the power amplifying circuit 1 according to the first embodiment includes inductors 111 and 112, an amplifier 120, an amplifier 130, a harmonic processing circuit 140, inductors 151, 152, 153, and 166, capacitors 154, 162, 165, and 169, switches 161, 163, 164, 167, and 168, and output terminals 180 and 181. Note that the black dots added in the vicinities of the inductors 151, 152, and 153 indicate the polarities of those inductors. The same applies to other drawings referenced in the description below.

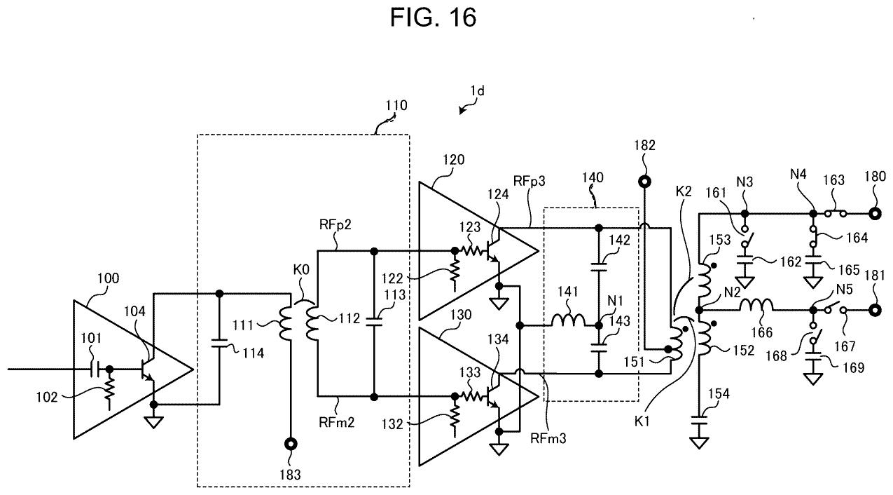

The amplifier 120 that is the first amplifier and the amplifier 130 that is the second amplifier constitute a differential amplifier that corresponds to a differential power stage. In some cases, a preamplifier, which will be described below, is provided in a stage that precedes the differential power stage made up of the amplifier 120 and the amplifier 130 (see FIG. 16).

The inductors 111 and 112 are provided on the input side of the amplifier 120 and the amplifier 130. The inductor 111 and the inductor 112 are magnetically coupled with each other. A curve K0 in FIG. 2 indicates the presence of magnetic coupling. A signal from a preceding stage is inputted to the inductor 111. A power supply 183 is connected to the inductor 111.

The amplifier 120 includes a transistor 124, a capacitor 121, and resistors 122 and 123. One end portion of the capacitor 121 is connected to one end portion of the inductor 112.

The transistor 124 includes a collector that serves as an output port of the amplifier 120, a base that is connected to the other end portion of the capacitor 121 via the resistor 123, and an emitter connected to a reference potential. One end portion of the resistor 122 is connected to a connecting point of the capacitor 121 and the resistor 123. A bias circuit that is not illustrated is connected to the other end portion of the resistor 122. The capacitor 121 is provided to cut off a DC current. The amplifier 120 amplifies a signal RFp2 supplied from the one end portion of the inductor 112 and outputs a signal RFp3. Note that the reference potential is, for example, ground potential. The same applies to the description below.

The amplifier 130 includes a transistor 134, a capacitor 131, and resistors 132 and 133. One end portion of the capacitor 131 is connected to the other end portion of the inductor 112.

The transistor 134 includes a collector that serves as an output port of the amplifier 130, a base that is connected to the other end portion of the capacitor 131 via the resistor 133, and an emitter connected to the reference potential. One end portion of the resistor 132 is connected to a connecting point of the capacitor 131 and the resistor 133. A bias circuit that is not illustrated is connected to the other end portion of the resistor 132. The capacitor 131 is provided to cut off a DC current. The amplifier 130 amplifies a signal RFm2 supplied from the other end portion of the inductor 112 and outputs a signal RFm3.

The inductor 151 corresponds to a first inductor of the present disclosure. A power supply 182 is connected to an intermediate point of the inductor 151. The power supply 182 is a power supply that supplies voltages to the amplifiers 120 and 130 using wiring lines that are not illustrated. That is to say, the power for the differential amplifier made up of the amplifiers 120 and 130 is supplied to the intermediate point of the inductor 151.

The inductor 152 corresponds to a second inductor of the present disclosure. The inductor 152 and the inductor 151 are magnetically coupled with each other. A curve K1 in FIG. 2 indicates the presence of magnetic coupling. The inductor 153 corresponds to a third inductor of the present disclosure. The inductor 153 and the inductor 151 are magnetically coupled with each other. A curve K2 in FIG. 2 indicates the presence of magnetic coupling. The inductors 151, 152, and 153 function as a balun.

Each of the inductors 151, 152, and 153 is realized, for example, by a wiring pattern provided on a multilayer printed circuit board (PCB). That is to say, for example, wiring patterns respectively corresponding to the inductors 151, 152, and 153 are provided at mutually different layers of a PCB. The magnetic coupling between the inductors can be realized by arranging the wiring patterns such that they overlap each other in a plan view of a principal surface of the PCB.

One end portion of the inductor 152 and one end portion of the inductor 153 are connected to each other at a connecting point N2. The other end portion of the inductor 153 is connected to the output terminal 180 via the switch 163. The switch 163 is provided between the other end portion of the inductor 153 and the output terminal 180.

The switch 163 corresponds to a second switch of the present disclosure. The output terminal 180 corresponds to a second output terminal of the present disclosure. For example, the output terminal 180 outputs a signal in the 2G mode.

The other end portion of the inductor 152 is connected to one end portion of the capacitor 154. The other end portion of the capacitor 154 is connected to the reference potential. The capacitor 154 corresponds to a first capacitor of the present disclosure.

The inductor 166 corresponds to a fourth inductor of the present disclosure. One end portion of the inductor 166 is connected to the connecting point N2. The other end portion of the inductor 166 is connected to the output terminal 181 via the switch 167. The output terminal 181 corresponds to a first output terminal of the present disclosure. For example, the output terminal 181 outputs a signal of a low band (LB) of a fifth-generation mobile communication system (5G mode) or a signal of a very low band (VLB) of the fifth-generation mobile communication system (5G mode).

The inductor 166 is provided between the connecting point N2 and the switch 167. The switch 167 corresponds to a first switch of the present disclosure.

One end portion of the switch 161 is connected to a connecting point N3 between the inductor 153 and the switch 163. The other end portion of the switch 161 is connected to one end portion of the capacitor 162. The other end portion of the capacitor 162 is connected to the reference potential. The capacitor 162 is connected between the other end portion of the switch 161 and the reference potential.

The switch 161 corresponds to a third switch of the present disclosure. The capacitor 162 corresponds to a second capacitor of the present disclosure.

One end portion of the switch 164 is connected to a connecting point N4 between the inductor 153 and the switch 163. The other end portion of the switch 164 is connected to one end portion of the capacitor 165. The other end portion of the capacitor 165 is connected to the reference potential. The capacitor 165 is connected between the other end portion of the switch 164 and the reference potential.

One end portion of the switch 168 is connected to a connecting point N5 between the inductor 166 and the switch 167. The other end portion of the switch 168 is connected to one end portion of the capacitor 169. The other end portion of the capacitor 169 is connected to the reference potential.

By controlling the switch 167, which is the first switch, the switch 163, which is the second switch, and the switch 161, which is the third switch, to be on or off, a signal of a desired frequency is outputted from the output terminal 181 or the output terminal 180. Each switch is controlled to be on or off by a control signal from a control part that is not illustrated.

### Harmonic Processing Circuit

The harmonic processing circuit 140 is provided on the output side of the amplifiers 120 and 130. The harmonic processing circuit 140 is connected between the collector of the transistor 124, which is the output port of the amplifier 120, and the collector of the transistor 134, which is the output port of the amplifier 130. The harmonic processing circuit 140 is connected in parallel to the inductor 151. Here, “connected in parallel” refers to the state where the harmonic processing circuit 140 and the inductor 151 are lined up in a row in between the output port of the amplifier 120 and the output port of the amplifier 130. More specifically, one end portion (one end portion of a capacitor 142 which will be described below) and the other end portion (one end portion of a capacitor 143 which will be described below) of the harmonic processing circuit 140 are connected to one end portion and the other end portion of the inductor 151, respectively. Because the harmonic processing circuit 140 is shared by the amplifier 120 and the amplifier 130, there is no need for providing a separate harmonic processing circuit 140 for each of the amplifier 120 and the amplifier 130. Therefore, it becomes possible to reduce the scale of the power amplifying circuit.

The harmonic processing circuit 140 includes the capacitor 142, the capacitor 143, and an inductor 141. The capacitor 142 corresponds to a third capacitor of the present disclosure. The capacitor 143 corresponds to a fourth capacitor of the present disclosure. The inductor 141 corresponds to a sixth inductor of the present disclosure.

One end portion of the capacitor 142 is connected to the output port of the amplifier 120. One end portion of the capacitor 143 is connected to the output port of the amplifier 130. A connecting point N1 of the other end portion of the capacitor 142 and the other end portion of the capacitor 143 is connected to one end portion of the inductor 141. The other end portion of the inductor 141 is connected to the reference potential. According to the harmonic processing circuit 140, it becomes possible to provide matching on the output side of the amplifiers 120 and 130.

### States of Switches

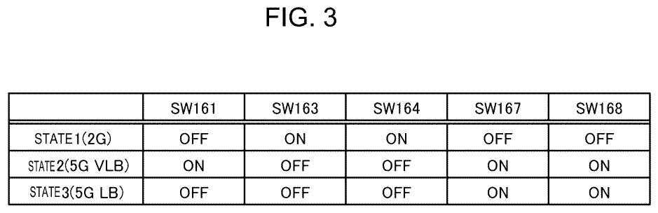

FIG. 3 is a diagram illustrating the operating state of each switch. “SW161” in FIG. 3 corresponds to the switch 161 in FIG. 2, “SW163” corresponds to the switch 163 in FIG. 2, “SW164” corresponds to the switch 164 in FIG. 2, “SW167” corresponds to the switch 167 in FIG. 2, and “SW168” corresponds to the switch 168 in FIG. 2.

“State 1” in FIG. 3 denotes the state of each switch when a signal of a band of a second-generation mobile communication system (2G) is outputted (that is, 2G mode). In the “State 1”, the switch 161 is “OFF”, the switches 163 and 164 are “ON”, and the switches 167 and 168 are “OFF”. Because of this, the inductor 153 is electrically connected to the output terminal 180, and further, the capacitor 165 is electrically connected to the connecting point N4.

This “State 1” corresponds to a third mode of the power amplifying circuit of the present disclosure. Because the switch 163 is “ON”, the output terminal 180 is used.

Because the switch 167 is “OFF”, the output terminal 181 is not used.

In the third mode, the first switch 167 is off, the second switch 163 is on, the third switch 161 is off, and a signal of a third frequency (2G) included in “5G LB” that is a first frequency is outputted from the output terminal 180.

“State 2” in FIG. 3 denotes the state of each switch when a signal of the very low band (VLB) of the fifth-generation mobile communication system (5G) is outputted (hereinbelow, referred to as “5G VLB”). In the “State 2” in FIG. 3, the switch 161 is “ON”, the switches 163 and 164 are “OFF”, and the switches 167 and 168 are “ON”. Because of this, the connecting point N2 of the inductor 153 and the inductor 152 is electrically connected to the output terminal 181 via the inductor 166, and further, the capacitor 169 is connected to the connecting point N5. Furthermore, the capacitor 162 is electrically connected to the connecting point N3.

This “State 2” corresponds to a second mode of the power amplifying circuit of the present disclosure. Because the switch 163 is “OFF”, the output terminal 180 is not used. Because the switch 167 is “ON”, the output terminal 181 is used.

In the second mode, the first switch 167 is on, the second switch 163 is off, the third switch 161 is on, and a signal of a second frequency “5G VLB”, which is different from the signal of “5G LB” that is the first frequency, is outputted from the first output terminal 181.

“State 3” in FIG. 3 denotes the state of each switch when a signal of the low band (LB) of the fifth-generation mobile communication system (5G) is outputted (hereinbelow, referred to as “5G LB”). In the “State 3” in FIG. 3, the switch 161 is “OFF”, the switches 163 and 164 are “OFF”, and the switches 167 and 168 are “ON”. Because of this, the connecting point N2 of the inductor 153 and the inductor 152 is electrically connected to the output terminal 181 via the inductor 166, and further, the capacitor 169 is electrically connected to the connecting point N5.

This “State 3” corresponds to a first mode of the power amplifying circuit of the present disclosure. Because the switch 163 is “OFF”, the output terminal 180 is not used. Because the switch 167 is “ON”, the output terminal 181 is used.

In the first mode, the first switch 167 is on, the second switch 163 is off, the third switch 161 is off, and a signal of “5G LB” that is the first frequency is outputted from the first output terminal 181.

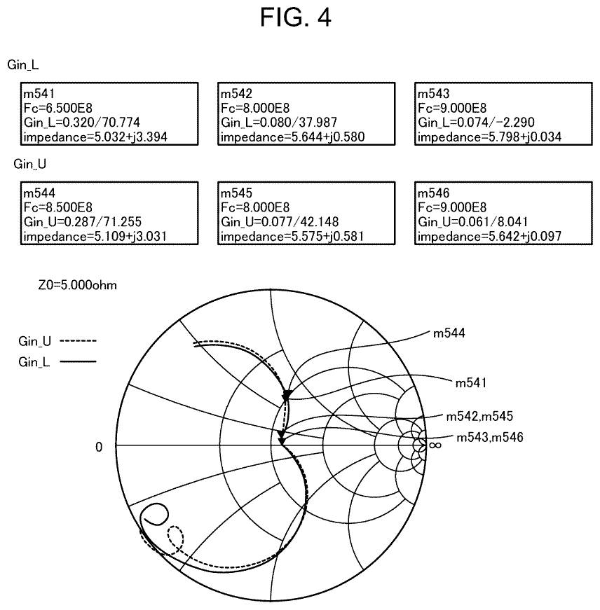

In FIG. 3, when attention is directed to the “State 3”, where a signal of “5G LB” is outputted, the switch 161 is “OFF”. FIG. 4 illustrates the load impedances of the amplifiers 120 and 130 in this case. FIG. 4 is a Smith chart that illustrates the load impedances of the amplifiers 120 and 130 in the “State 3” in FIG. 3. Referring to FIG. 4, the impedances from 800 MHZ to 900 MHZ in the “State 3” in FIG. 3 are at approximately the same location for both the amplifier 120 and the amplifier 130. In contrast, at 650 MHz, it is clear that the locations of the impedances are deviated from each other.

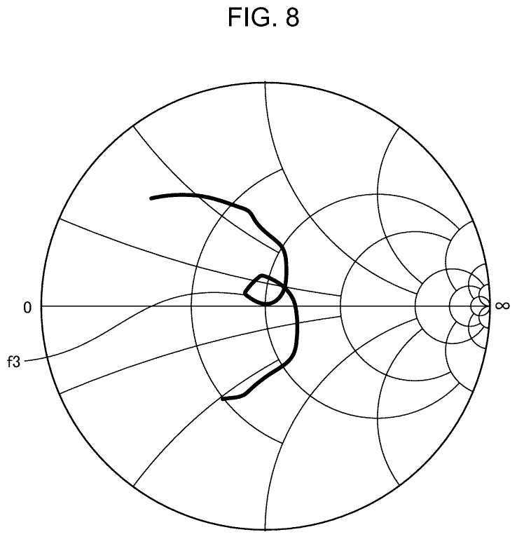

In contrast, in FIG. 3, when attention is directed to the “State 2”, where a signal of “5G VLB” is outputted, the switch 161 is “ON”. Referring to FIG. 2, when the black dot of the inductor 152 and the black dot of the inductor 153 are seen from the connecting point N2 of the inductor 152 and the inductor 153, the turning directions of the currents flowing through those inductors are opposite to each other. This causes weakening of the magnetic coupling of the inductor 151 with the inductors 152 and 153. The weakening of the magnetic coupling of the inductor 151 with the inductors 152 and 153 enables the reduction in the size of a spiral of the impedance, as is the case with FIG. 8. In other words, the variation in the impedance with respect to the frequency can be suppressed. In the 2G mode, the operating frequency is, for example, from 824 MHz to 915 MHz. Further, in the 5G mode, the operating frequency is, for example, from 663 MHZ to 915 MHZ. In this wide band operating frequency of the 5G mode, a constant load impedance is realized using a series circuit made up of the switch 161 and the capacitor 162.

### Workings

FIG. 4 is a Smith chart illustrating the impedance seen from each of the amplifiers in FIG. 2 toward the output side. “Gin_U” illustrated by the dashed line in FIG. 4 is the impedance seen from the collector end of the transistor 124 of the amplifier 120 toward the output side. “Gin_L” illustrated by the solid line in FIG. 4 is the impedance seen from the collector end of the transistor 134 of the amplifier 130 toward the output side. Referring to FIG. 4, because of the difference in frequency, the locations of the markers spread out, and it is difficult to bring those locations closer together.

Note that in FIG. 4, the location of a marker m541 is at the frequency Fc=650 MHZ, the reflection coefficient Gin_L=0.320/70.774, and the impedance=5.032+j3.394. The location of a marker m542 is at the frequency Fc=800 MHZ, the reflection coefficient Gin_L=0.080/37.987, and the impedance=5.644+j0.580. The location of a marker m543 is at the frequency Fc=900 MHZ, the reflection coefficient Gin_L=0.074/-2.290, and the impedance=5.798+j0.034. The location of a marker m544 is at the frequency Fc=650 MHZ, the reflection coefficient Gin_U=0.287/71.255, and the impedance=5.109+j3.031. The location of a marker m545 is at the frequency Fc=800 MHZ, the reflection coefficient Gin_U=0.077/42.148, and the impedance=5.575+j0.581. The location of a marker m546 is at the frequency Fc=900 MHZ, the reflection coefficient Gin_U=0.061/8.041, and the impedance=5.642+j0.097.

### Equivalent Circuit of Balun

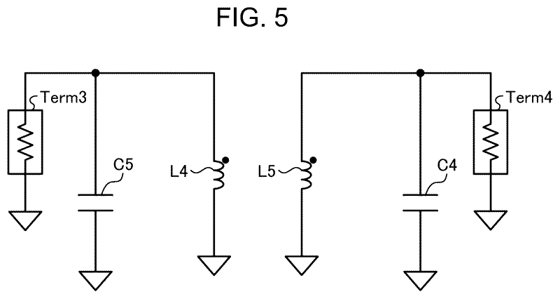

Here, FIG. 5 is a diagram illustrating one example of an equivalent circuit of a typical balun. The equivalent circuit illustrated in FIG. 5 includes a primary side inductor L4, a primary side termination resistor Term3, a primary side capacitor C5, a secondary side inductor L5, a secondary side termination resistor Term4, and a secondary side capacitor C4. One end portion of the inductor L4 is connected to one end portion of the capacitor C5 and one end portion of the termination resistor Term3. The other end portion of the inductor L4, the other end portion of the capacitor C5, and the other end portion of the termination resistor Term3 are connected to the reference potential. The inductor L4 and the capacitor C5 are connected in parallel to each other in between a connecting point of the inductor L4 and the capacitor C5 and the reference potential. One end portion of the inductor L5 is connected to one end portion of the capacitor C4 and one end portion of the termination resistor Term4. The other end portion of the inductor L5, the other end portion of the capacitor C4, and the other end portion of the termination resistor Term4 are connected to the reference potential. The inductor L5 and the capacitor C4 are connected in parallel to each other in between a connecting point of the inductor L5 and the capacitor C4 and the reference potential. The inductor L4 and the inductor L5 are magnetically coupled with each other. Note that the capacitor C4 corresponds to the capacitor 169 in FIG. 2.

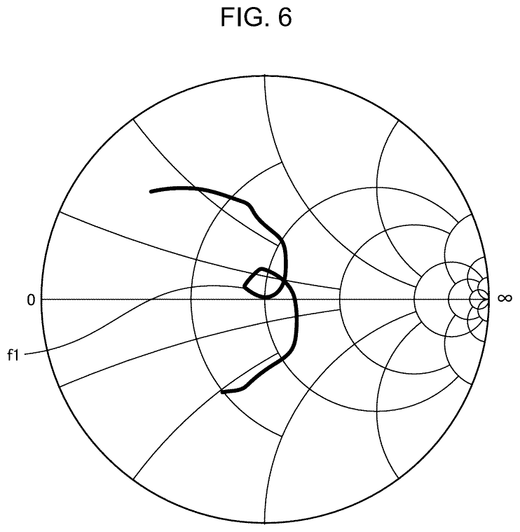

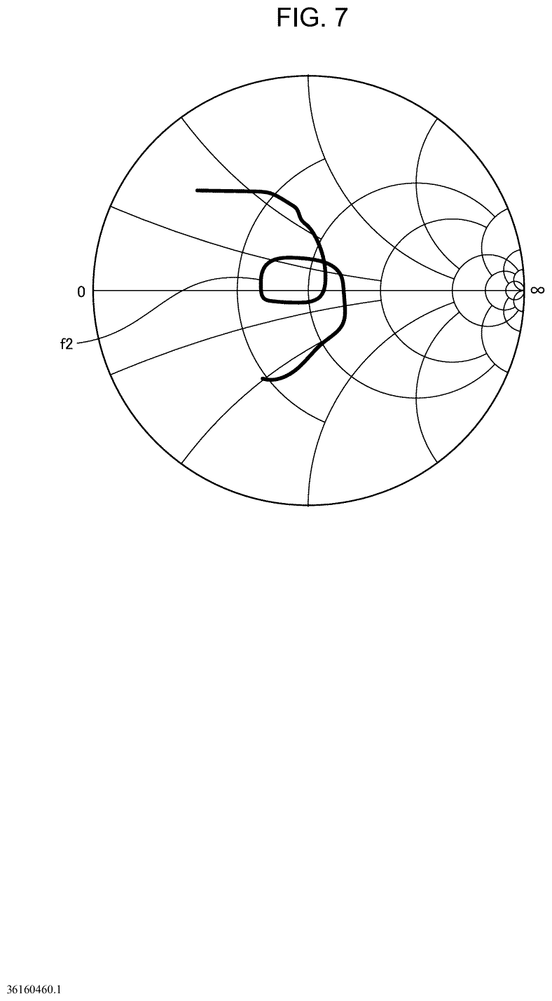

A case is described in which a balun having the equivalent circuit of FIG. 5 is used as the matching circuit of a power amplifier. FIG. 6, FIG. 7, and FIG. 8 are Smith charts each illustrating the impedance seen from the primary side termination resistor Term3 when the circuit of FIG. 5 is used as a matching circuit of the power amplifier.

With a characteristic f1 illustrated in FIG. 6, when the capacitance value of the capacitor C4 is increased, a resonant frequency decreases, and the spiral of the impedance becomes larger as in a characteristic f2 illustrated in FIG. 7. When the spiral of the impedance is large, the impedance varies greatly with respect to the frequency, and this is undesirable.

In view of this, it is conceivable to increase the capacitance value of the capacitor C4 and decrease the coupling coefficient of the inductor. This allows only the resonant frequency to decrease, as in a characteristic f3 illustrated in FIG. 8. In this case, the spiral of the impedance does not become larger. In other words, the variation in the impedance with respect to the frequency can be suppressed.

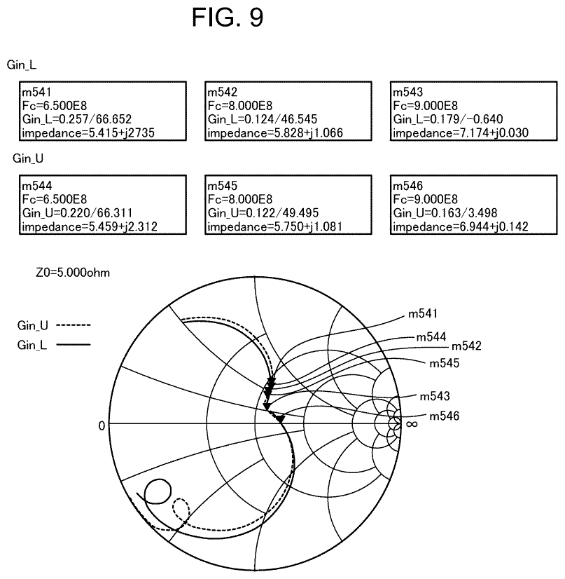

In the present embodiment, the switch 161 is turned on in the “State 2” in FIG. 3. By turning the switch 161 on, the connecting point N3 is connected to the capacitor 162, and the capacitance value being connected increases. Further, in the present embodiment, when the black dot of the inductor 152 and the black dot of the inductor 153 are seen from the connecting point N2 of the inductor 152 and the inductor 153, the turning directions of the currents flowing through those inductors are opposite to each other. At the time of turning the switch 161 on and outputting a signal from the output terminal 181, this causes weakening of the magnetic coupling of the inductor 151 with the inductors 152 and 153. Because of this, as in the characteristic f3 illustrated in FIG. 8, it becomes possible to decrease only the resonant frequency and decrease the frequency at which the impedances become nearly equal. Because of this, it becomes possible to change the characteristic illustrated in FIG. 4 to the characteristic illustrated FIG. 9.

FIG. 9 is a Smith chart illustrating the impedance seen from each of the amplifiers in FIG. 2 toward the output side. “Gin_U” illustrated by the dashed line in FIG. 9 is the impedance seen from the collector end of the transistor 124 of the amplifier 120 toward the output side. “Gin_L” illustrated by the solid line in FIG. 9 is the impedance seen from the collector end of the transistor 134 of the amplifier 130 toward the output side. Referring to FIG. 9, compared with the case of FIG. 4, the locations of the markers spread out less, and it becomes possible to bring those locations closer together. Accordingly, compared with the case of FIG. 4, in the case of FIG. 9, the variation in the impedance with respect to the frequency becomes smaller.

Note that in FIG. 9, the location of the marker m541 is at the frequency Fc=650 MHz, the reflection coefficient Gin_L=0.257/66.652, and the impedance=5.415+j2.735. The location of the marker m542 is at the frequency Fc=800 MHz, the reflection coefficient Gin_L=0.124/46.545, and the impedance=5.828+j1.066. The location of the marker m543 is at the frequency Fc=900 MHZ, the reflection coefficient Gin_L=0.179/-0.640, and the impedance=7.174+j0. 030. The location of the marker m544 is at the frequency Fc=650 MHz, the reflection coefficient Gin_U=0.220/66.311, and the impedance=5.459+j2.312. The location of the marker m545 is at the frequency Fc=800MHz, the reflection coefficient Gin_U=0.122/49.495, and the impedance=5.750+j1. 081. The location of the marker m546 is at the frequency Fc=900 MHZ, the reflection coefficient Gin_U=0.163/3.498, and the impedance=6.944+j0.142.

### Second Embodiment

### Configuration

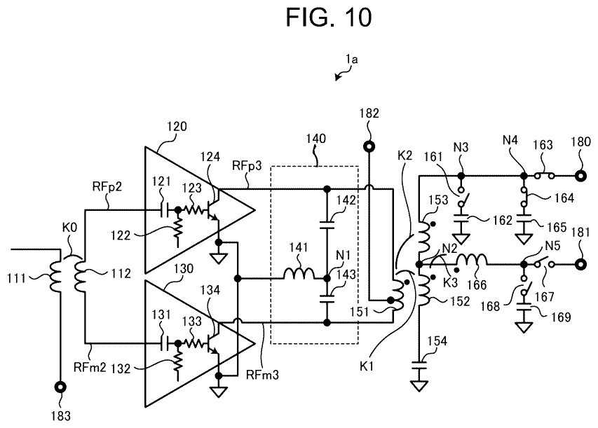

FIG. 10 is a diagram illustrating a power amplifying circuit 1a according to the second embodiment. In FIG. 10, the power amplifying circuit 1a according to the second embodiment includes inductors 111 and 112, an amplifier 120, an amplifier 130, a harmonic processing circuit 140, inductors 151, 152, 153, and 166, capacitors 154, 162, 165, and 169, switches 161, 163, 164, 167, and 168, and output terminals 180 and 181.

The inductor 166, which is the fourth inductor, and the inductor 152, which is the second inductor, are magnetically coupled with each other. A curve K3 indicates the presence of magnetic coupling.

Each of the inductors 151, 152, 153, and 166 is realized, for example, by a wiring pattern provided on a multilayer PCB. That is to say, for example, wiring patterns respectively corresponding to the inductors 151, 152, 153, and 166 are provided at mutually different layers of a PCB. The magnetic coupling between the inductors can be realized by arranging the wiring patterns such that they overlap each other in a plan view of a principal surface of the PCB. In this case, the direction of turning of the pattern corresponding to the inductor 166 is opposite to the direction of turning of the pattern corresponding to the inductor 152. Because of this, the turning direction of the current flowing through the inductor 152 is opposite to the turning direction of the current flowing through the inductor 166. The inductors 151, 152, 153, and 166 function as a balun. In the present embodiment, the matching circuit for this balun is caused to operate in a wide band.

### Workings

In FIG. 10, when a signal of “5G VLB” is outputted, the switch 161 is “ON”. When the black dot of the inductor 152 and the black dot of the inductor 153 are seen from the connecting point N2 of the inductor 152 and the inductor 153, the turning directions of the currents flowing through those inductors are opposite to each other. This causes weakening of the magnetic coupling of the inductor 151 with the inductors 152 and 153 at the time of outputting a signal from the output terminal 181. The weakening of the magnetic coupling between the inductor 151 and the inductor 152 enables the reduction in the size of the spiral of the impedance, as is the case with FIG. 9. In other words, the variation in the impedance with respect to the frequency can be suppressed.

In FIG. 10, in addition to the configuration of FIG. 2, inverse magnetic coupling between the inductor 166 and the inductor 152 is added. In this case, the magnetic coupling between the inductor 151 and the inductor 152 is further weakened, compared with the case of FIG. 2. More specifically, in the case of FIG. 2, the switch 161 is turned on only in the time of 5G VLB (“State 2” in FIG. 3), and this weakens the magnetic coupling between the inductor 151 and the inductor 152. In the case of FIG. 10, due to the effect of the consistent presence of the inverse magnetic coupling between the inductor 166 and the inductor 152, the state of the magnetic coupling between the inductor 151 and the inductor 152 is weakened in both the 5G LB and the 5G VLB. That is to say, in the 5G VLB, compared with the case of FIG. 2, the size of the spiral of the impedance is further reduced in the case of FIG. 10. Accordingly, for the 5G VLB, compared with the case of FIG. 2, the variation in the impedance with respect to the frequency is further reduced in the case of FIG. 10.

### Third Embodiment

### Configuration

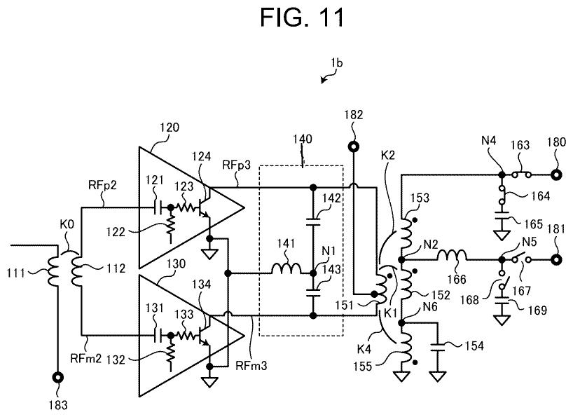

FIG. 11 is a diagram illustrating a power amplifying circuit 1b according to the third embodiment. In FIG. 11, the configuration of the power amplifying circuit 1b is such that an inductor 155 is added to the power amplifying circuit 1 according to the first embodiment. Further, the configuration of the power amplifying circuit 1b is such that the switch 161 and the capacitor 162 are removed from the power amplifying circuit 1 according to the first embodiment.

The inductor 155 corresponds to a fifth inductor of the present disclosure. One end portion of the inductor 155 is connected to a connecting point N6 of the inductor 152 and the capacitor 154. The other end portion of the inductor 155 is connected to the reference potential. The inductor 155 and the inductor 151 are magnetically coupled with each other. A curve K4 indicates the presence of magnetic coupling.

Each of the inductors 151, 152, 153, and 155 is realized, for example, by a wiring pattern provided on a multilayer printed circuit board (PCB). That is to say, for example, wiring patterns respectively corresponding to the inductors 151, 152, 153, and 155 are provided at mutually different layers of a PCB. The magnetic coupling between the inductors can be realized by arranging the wiring patterns such that they overlap each other in a plan view of a principal surface of the PCB. In this case, the direction of turning of the pattern corresponding to the inductor 155 is opposite to the direction of turning of the patterns corresponding to the inductors 152 and 153. Because of this, the turning direction of the current flowing through the inductor 151 is opposite to the turning direction of the current flowing through the inductor 155. The inductors 151, 152, 153, and 155 function as a balun.

### Workings

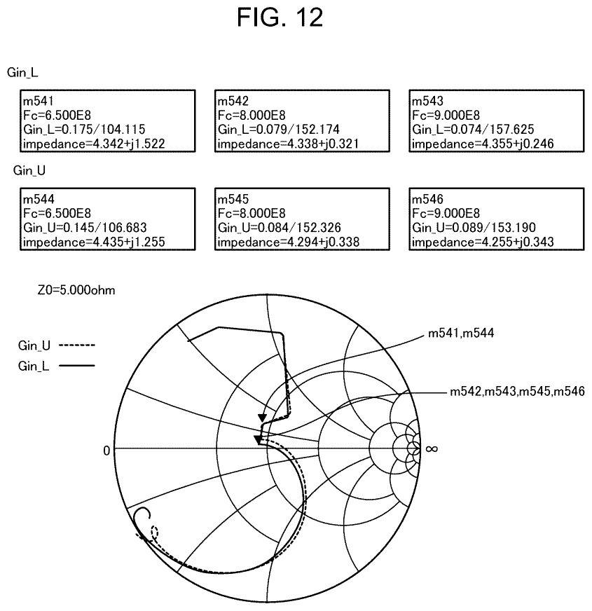

FIG. 12 is a Smith chart illustrating the impedance seen from each of the amplifiers in FIG. 11 toward the output side. “Gin_U” illustrated by the dashed line in FIG. 11 is the impedance seen from the collector end of the transistor 124 of the amplifier 120 toward the output side. “Gin_L” illustrated by the solid line in FIG. 11 is the impedance seen from the collector end of the transistor 134 of the amplifier 130 toward the output side. Referring to FIG. 11, compared with the case of FIG. 4, the locations of the markers spread out less, and it becomes possible to bring those locations closer together.

Note that in FIG. 12, the location of the marker m541 is at the frequency Fc=650 MHz, the reflection coefficient Gin_L=0.175/104.115, and the impedance=4.342+j1.522. The location of the marker m542 is at the frequency Fc=800 MHZ, the reflection coefficient Gin_L=0.079/152.174, and the impedance=4.338+j0.321. The location of the marker m543 is at the frequency Fc=900 MHz, the reflection coefficient Gin_L=0.074/157. 625, and the impedance=4.355+j0.246. The location of the marker m544 is at the frequency Fc=650 MHZ, the reflection coefficient Gin_U=0.145/106.683, and the impedance=4.435+j1.255. The location of the marker m545 is at the frequency Fc=800 MHZ, the reflection coefficient Gin_U=0.084/152.326, and the impedance=4.294+j0.338. The location of the marker m546 is at the frequency Fc=900 MHz, the reflection coefficient Gin_U=0.089/153.190, and the impedance=4.255+j0.343.

As described above, according to the power amplifying circuit 1b according to the present embodiment, it becomes possible to set the load impedances of the amplifiers 120 and 130 for a wide band as illustrated in FIG. 12 in the 5G LB of the “State 3”, compared with the case of the first embodiment. Specifically, in the power amplifying circuit 1b according to the present embodiment, the inductor 151 and the inductor 155 form magnetic coupling, and thus, the inductor 152 and the capacitor 154 do not function as a low pass filter. When the inductor 152 and the capacitor 154 do not function as a low pass filter, no signal attenuation occurs particularly on the high frequency side, and because of this, the power amplifying circuit 1b functions to widen the frequency band in which preferable impedance matching is provided. Accordingly, even in the case where the switch 161 and the capacitor 162 are not included, the load impedances of the amplifiers 120 and 130 can be set for a wide band as illustrated in FIG. 12.

### Fourth Embodiment

### Configuration

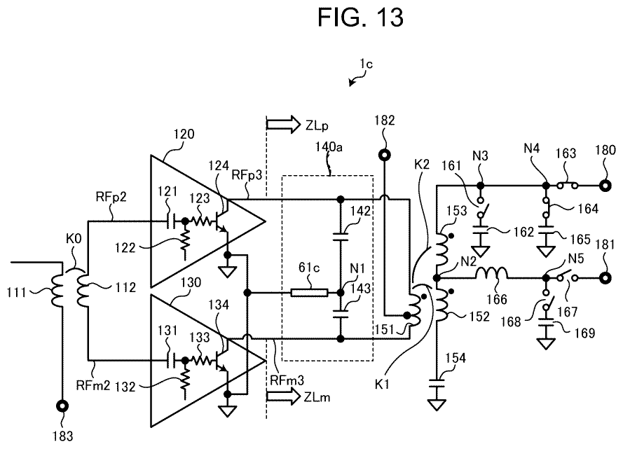

FIG. 13 is a diagram illustrating a power amplifying circuit 1c according to the fourth embodiment. The power amplifying circuit 1c according to the fourth embodiment employs a harmonic processing circuit 140a that uses a microstrip line instead of the harmonic processing circuit 140 in the power amplifying circuit 1 of the first embodiment.

In FIG. 13, the harmonic processing circuit 140a includes a third capacitor 142, a fourth capacitor 143, and a microstrip line 61c. One end portion of the third capacitor 142 is connected to the output port of the amplifier 120. One end portion of the fourth capacitor 143 is connected to the output port of the amplifier 130. The other end portion of the third capacitor 142 and the other end portion of the fourth capacitor 143 are connected together at the connecting point N1. One end portion of the microstrip line 61c is connected to the connecting point N1. The other end portion of the microstrip line 61c is connected to the reference potential. The microstrip line 61c is formed in a linear shape, for example.

### Workings

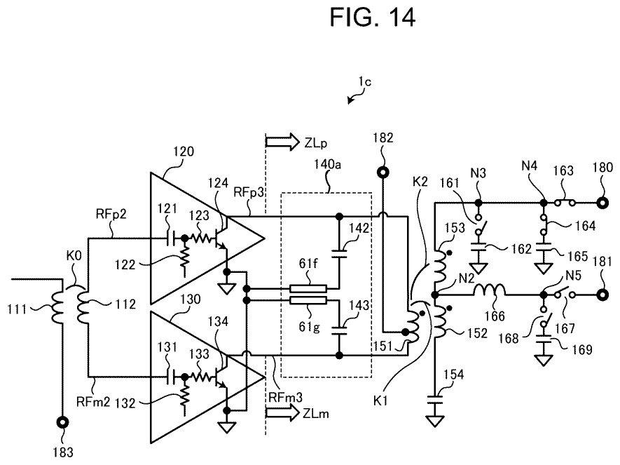

FIG. 14 is a diagram to illustrate how the circuit appears at even-order harmonic waves of the harmonic processing circuit 140a of the power amplifying circuit 1c according to the fourth embodiment. When the harmonic waves are even-order harmonic waves, the phase of the signal outputted from the amplifier 120 becomes approximately equal to the phase of the signal outputted from the output port of the amplifier 130, and thus, the potential of the output port of the amplifier 120 becomes approximately equal to the potential of the output port of the amplifier 130.

Because of this, no current flows from the output port of the amplifier 120 to the output port of the amplifier 130 through the third capacitor 142 and the fourth capacitor 143. Accordingly, from the output port of the amplifier 120, it appears that the output port of the amplifier 120 is not connected to the output port of the amplifier 130 through the third capacitor 142 and the fourth capacitor 143.

On the other hand, because the potential of the output port of the amplifier 130 is different from the reference potential, a current flows from the output port of the amplifier 120 to the reference potential through the third capacitor 142 and the microstrip line 61c (see FIG. 13). Accordingly, from the output port of the amplifier 120, it appears that the output port of the amplifier 120 is connected to the reference potential through the third capacitor 142 and a microstrip line 61f (see FIG. 14).

An impedance ZLp for the even-order harmonic waves seen from the output port of the amplifier 120 toward the harmonic processing circuit 140a can be adjusted using the capacitance of the third capacitor 142 and the inductance of the microstrip line 61f. Similarly, an impedance ZLm for the even-order harmonic waves seen from the output port of the amplifier 130 toward the harmonic processing circuit 140a can be adjusted using the capacitance of the fourth capacitor 143 and the inductance of a microstrip line 61g.

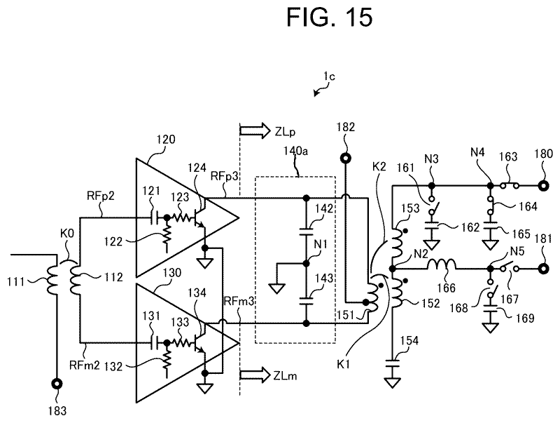

FIG. 15 is a diagram to illustrate how the circuit appears at a fundamental wave and odd-order harmonic waves of the harmonic processing circuit 140a of the power amplifying circuit 1c according to the fourth embodiment. As illustrated in FIG. 15, when the harmonic waves are the fundamental wave and the odd-order harmonic waves, the phase of the signal outputted from the amplifier 120 differs from the phase of the signal outputted from the output port of the amplifier 130 by approximately 180 degrees, and thus, the connecting point N1 is virtually short-circuited. Accordingly, from the output port of the amplifier 120, it appears that the output port of the amplifier 120 is connected to the reference potential through the third capacitor 142. Similarly, from the output port of the amplifier 130, it appears that the output port of the amplifier 130 is connected to the reference potential through the fourth capacitor 143.

The impedance ZLp for the fundamental wave and the odd-order harmonic waves seen from the output port of the amplifier 120 toward the harmonic processing circuit 140a can be adjusted using the capacitance of the third capacitor 142. Similarly, the impedance ZLm for the fundamental wave and the odd-order harmonic waves seen from the output port of the amplifier 130 toward the harmonic processing circuit 140a can be adjusted using the capacitance of the fourth capacitor 143.

### Fifth Embodiment

### Configuration

FIG. 16 is a diagram illustrating a power amplifying circuit 1d according to the fifth embodiment. In FIG. 16, the power amplifying circuit 1d according to the fifth embodiment includes an amplifier 100 that serves as a preamplifier. The amplifier 100 is an amplifier in the driver stage. The amplifier 100 is provided in a stage that precedes the differential amplifier made up of the amplifiers 120 and 130.

An inter-stage matching circuit 110 is provided between the amplifier 100 and the differential amplifier made up of the amplifiers 120 and 130. The inter-stage matching circuit 110 includes the inductors 111 and 112 and the capacitors 113 and 114.

The inductor 111 and the inductor 112 are magnetically coupled with each other. One end portion of the inductor 111 is connected to the output port of the amplifier 100. The other end portion of the inductor 111 is connected to the power supply 183. The inductor 111 corresponds to a seventh inductor of the present disclosure. One end portion of the inductor 112 is connected to the input port of the amplifier 120. The other end portion of the inductor 112 is connected to the input port of the amplifier 130. The inductor 112 corresponds to an eighth inductor of the present disclosure.

The capacitor 114 is connected in parallel to the inductor 111. The capacitor 113 is connected in parallel to the inductor 112. The capacitor 113 corresponds to the third capacitor of the present disclosure.

The amplifier 100 includes a transistor 104, a capacitor 101, and a resistor 102. The collector of the transistor 104 is connected to the one end portion of the inductor 111 and one end portion of the capacitor 114. The emitter of the transistor 104 is connected to the other end portion of the capacitor 114 and the reference potential. The base of the transistor 104 is connected to one end portion of the capacitor 101. One end portion of the resistor 102 is connected to a connecting point of the other end portion of the capacitor 101 and the base of the transistor 104. A bias circuit that is not illustrated is connected to the other end portion of the resistor 102.

When attention is directed to the transistor 124 of the amplifier 120, the emitter is connected to the reference potential, and the collector is connected to one end portion of the inductor 151. The signal at the one end portion of the inductor 112 is inputted to the base of the transistor 124. When attention is directed to the transistor 134 of the amplifier 130, the emitter is connected to the reference potential, and the collector is connected to the other end portion of the inductor 151. The signal at the other end portion of the inductor 112 is inputted to the base of the transistor 134.

The inter-stage matching circuit 110 sets the load impedance of the transistor 104 for a wide band and suppresses the effect of the parasitic capacitance between the base and emitter of each of the transistors 124 and 134, which varies according to the power level. This realizes the amplifier with favorable linearity over a wide band.

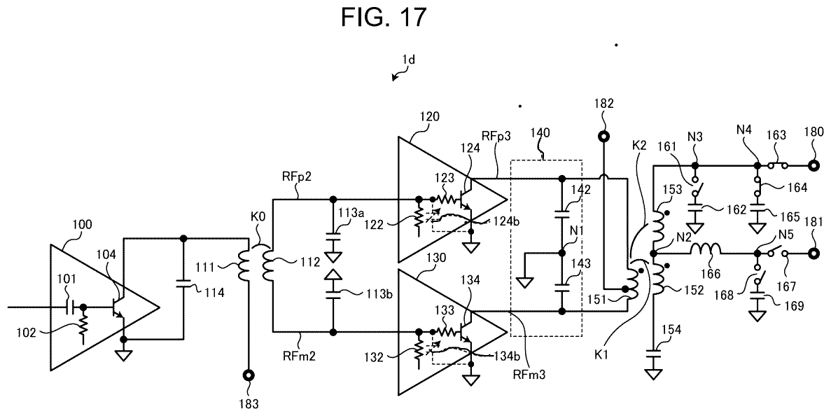

FIG. 17 is a diagram illustrating an equivalent circuit of the power amplifying circuit 1d illustrated in FIG. 16 at the fundamental wave frequency. In FIG. 17, a reference character 124b denotes the parasitic capacitance between the base and the emitter of the transistor 124, and a reference character 134b denotes the parasitic capacitance between the base and the emitter of the transistor 134.

When the parasitic capacitance 124b and a capacitor 113a are seen from the base of the transistor 124, the parasitic capacitance 124b and the capacitor 113a are connected in parallel between the base of the transistor 124 and the reference potential. Because of this, by appropriately selecting the capacitance value of the capacitor 113a, it becomes possible to reduce the effect of the parasitic capacitance 124b whose magnitude varies according to the power level. For example, the capacitance value of the capacitor 113a is set at a value that is substantially greater than the capacitance value of the parasitic capacitance 124b. By doing this, the effect of the variation in the parasitic capacitance 124b can be reduced. This enables the improvement in the linearity of the input to the transistor 124.

The same applies to the parasitic capacitance 134b between the base and the emitter of the transistor 134. That is to say, by appropriately selecting the capacitance value of a capacitor 113b, it becomes possible to reduce the effect of the parasitic capacitance 134b whose magnitude varies according to the power level. This enables the improvement in the linearity of the input to the transistor 134.

Now, the frequency characteristics of the load impedance of the collector of the transistor 104 in the amplifier 100 are considered. Compared with the power amplifying circuit 1 according to the first embodiment illustrated in FIG. 2, in the power amplifying circuit 1d according to the present embodiment, the capacitor 121 on the base side of transistor 124 and the capacitor 131 on the base side of the transistor 134 are not provided. These capacitors 121 and 131 are provided to cut off the DC current. However, these capacitors 121 and 131 have frequency dependence and affect the load impedance of the collector of the transistor 104.

In view of this, the power amplifying circuit 1d of the present embodiment does not include these capacitors 121 and 131. Even in this case, if the bias voltage supplied via the resistor 122 and the bias voltage supplied via the resistor 132 are the same, no current flows. This results in the same effect as the cutting off the DC current. Because the power amplifying circuit 1d according to the present embodiment does not include these capacitors 121 and 131, the power amplifying circuit 1d according to the present embodiment can reduce the frequency variation in the load impedance of the collector of the transistor 104.

Note that in FIG. 16, the location of the resistor 122 may be changed in such a way that the resistor 122 is connected between the base of the transistor 124 and the resistor 123 to supply the bias voltage via the resistor 122. Similarly, the location of the resistor 132 may be changed in such a way that the resistor 132 is connected between the base of the transistor 134 and the resistor 133 to supply the bias voltage via the resistor 132.

### Sixth Embodiment

### Configuration

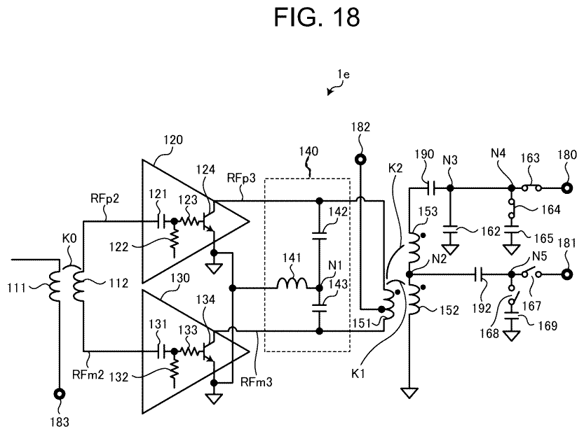

FIG. 18 is a diagram illustrating a power amplifying circuit 1e according to the sixth embodiment. Compared with the power amplifying circuit 1 of the first embodiment, in the power amplifying circuit 1e according to the sixth embodiment, capacitors 190 and 192 are added, and the capacitor 154, the inductor 166, and the switch 161 are removed.

The capacitor 190 is connected in series between the other end portion of the inductor 153 and the connecting point N3. The capacitor 192 is connected in series between the other end portion of the inductor 152 and the connecting point N5.

In the present embodiment, the inductor 166 that is included in the power amplifying circuit 1 of the first embodiment is removed. In the power amplifying circuit 1 of the first embodiment, the inductor 166 is not magnetically coupled with any other inductor. Because of this, the locations of the markers of the impedance seen from the collector end of the transistor 124 of the amplifier 120 toward the output side and the impedance seen from the collector end of the transistor 134 of the amplifier 130 toward the output side tend to spread out. In contrast, in the present embodiment, by removing the inductor 166, it becomes easier to bring the locations of the markers of the impedance seen from the collector end of the transistor 124 of the amplifier 120 toward the output side and the impedance seen from the collector end of the transistor 134 of the amplifier 130 toward the output side closer together. That is to say, it is easy to reduce the variation in the impedance with respect to the change in the frequency.

Further, in the present embodiment, the resonant frequency of the series circuit made up of the inductor 152 and the capacitor 169 is set at a center frequency of a 5G mode operating frequency (for example, 663 MHZ-915 MHZ). Because of this, the variation in the impedance seen from the collector end of the transistor 124 of the amplifier 120 toward the output side and the variation in the impedance seen from the collector end of the transistor 134 of the amplifier 130 toward the output side are further reduced with respect to the change in the frequency.

As described above, in the present embodiment, the load impedances of the amplifiers 120 and 130 can be set for a wide band even without including the switch 161, which is turned on and off to make the variation in the impedance with respect to the change in the frequency smaller in the power amplifying circuit 1 of the first embodiment.

Note that by removing the inductor 166, the impedance seen from the collector end of the transistor 124 of the amplifier 120 toward the output side and the impedance seen from the collector end of the transistor 134 of the amplifier 130 toward the output side become lower than those in the power amplifying circuit 1 of the first embodiment. To address this, in the present embodiment, those impedances are increased by making the capacitance value of the capacitor 162 greater than that of the capacitor 162 in the power amplifying circuit 1, and particularly the characteristics in the 5G mode are maintained in a preferable manner.

Further, in the present embodiment, the capacitors 190 and 192 are further included. As described above, because the value of the capacitor 162 is made greater, it is necessary to increase the inductance of the inductor 152. Further, together with that, in order to maintain the winding ratio of the balun, it is necessary to increase the inductances of the inductors 151 and 153. Here, particularly when the power amplifying circuit 1e operates in the 2G mode, the inductance seen from the output terminal 180 toward the inductors 152 and 153 becomes greater. In view of this, the capacitor 190 is added to decrease the inductance that is seen from the output terminal 180 toward the inductors 152 and 153, and this enables the provision of an appropriate impedance matching even in the 2G mode.

Further, the capacitor 192 is added to decrease the inductance of the inductor 152 that is seen, and this enables the provision of an appropriate impedance matching even when the power amplifying circuit 1e operates in the 5G mode.

### Seventh Embodiment

### Configuration

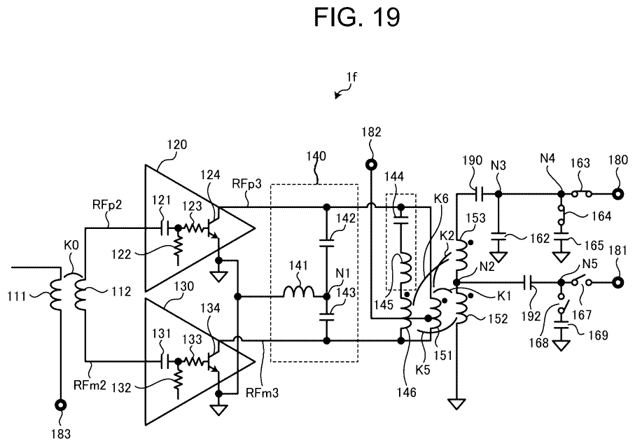

FIG. 19 is a diagram illustrating a power amplifying circuit 1f according to the seventh embodiment. Compared with the power amplifying circuit 1e of the sixth embodiment, the power amplifying circuit 1f according to the seventh embodiment further includes a capacitor 144 and inductors 145 and 146.

The capacitor 144 and the inductor 145 are connected in series to each other and form a series circuit. A resonant frequency of the series circuit made up of the capacitor 144 and the inductor 145 is set at a frequency equal to or higher than the operating frequency of the 5G mode. The inductor 146 is further connected in series to the series circuit made up of the capacitor 144 and the inductor 145. The series circuit made up of the capacitor 144 and the inductor 145 and the inductor 146 are connected between the other end portion of the capacitor 142 and the other end portion of the capacitor 143, forming a parallel connection with the inductor 151. Further, the inductor 146 is magnetically coupled with each of the inductors 152 and 153. Each of curves K5 and K6 indicates the presence of magnetic coupling.

When the power amplifying circuit 1f operates in the 2G mode, the state of the power amplifying circuit 1f becomes such that the series circuit made up of the capacitor 144 and the inductor 145 is connected in parallel to the inductor 151 that functions as the primary side winding of the balun. Because of this, the impedance of the inductor 146 cannot be seen, and consequently, only the inductor 151 can be seen as the primary side winding of the balun. Further, the inductors 152 and 153 function as the secondary side winding of the balun. Here, in the case where the inductances of the inductors 151, 152, and 153 are all the same, the ratio of the numbers of turns between the primary side winding of the balun, which is made up the inductor 151, and the secondary side winding, which is made up of the series circuit of the inductor 152 and the inductor 153, is 1:2.

On the other hand, when the power amplifying circuit 1f operates in the 5G mode, the series circuit made up of the capacitor 144 and the inductor 145 resonates, and the impedance thereof cannot be seen. Because of this, a parallel circuit made up of the inductor 151 and the inductor 146 functions as the primary side winding of the balun, and the inductor 153 functions as the secondary side winding of the balun. Accordingly, the ratio of the numbers of turns between the primary side winding and the secondary side winding of the balun becomes 1:2. As described above, in both the 2G mode and the 5G mode, it becomes possible to set the load impedances seen from the amplifiers 120 and 130 at approximately the same value.

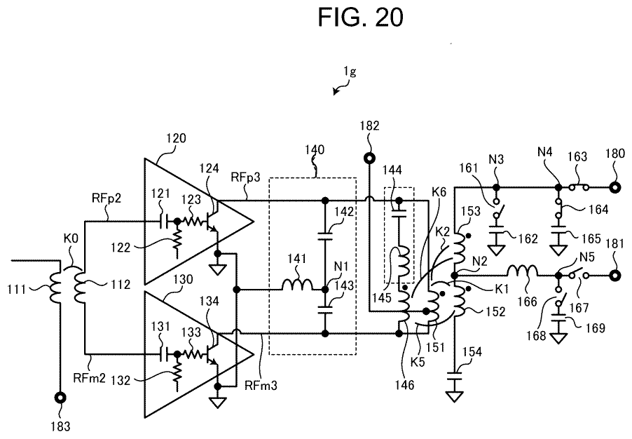

Note that FIG. 19 discloses the configuration in which the capacitor 144 and the inductors 145 and 146 are added to the power amplifying circuit 1e of the sixth embodiment. Alternatively, the capacitor 144 and the inductors 145 and 146 may be added to the power amplifying circuit 1 of the first embodiment. An example of such a configuration is now described with reference to FIG. 20.

### Eighth Embodiment

### Configuration

FIG. 20 is a diagram illustrating a power amplifying circuit 1g according to the eighth embodiment. Referring to FIG. 20, the series circuit made up of the capacitor 144 and the inductor 145 and the inductor 146 are connected between the other end portion of the capacitor 142 and the other end portion of the capacitor 143, forming a parallel connection with the inductor 151. Further, the inductor 146 is magnetically coupled with each of the inductors 152 and 153. By adding the capacitor 144 and the inductors 145 and 146, it becomes possible to produce a similar effect of being able to set the load impedances seen from the amplifiers 120 and 130 at approximately the same value in both the 2G mode and the 5G mode.

Further, the capacitor 144 and the inductors 145 and 146 may be added to the power amplifying circuits la to 1d of the second embodiment to the fifth embodiment. Even in such cases, by adding the capacitor 144 and the inductors 145 and 146, it becomes possible to produce a similar effect of being able to set the load impedances seen from the amplifiers 120 and 130 at approximately the same value in both the 2G mode and the 5G mode.

### Ninth Embodiment

### Configuration

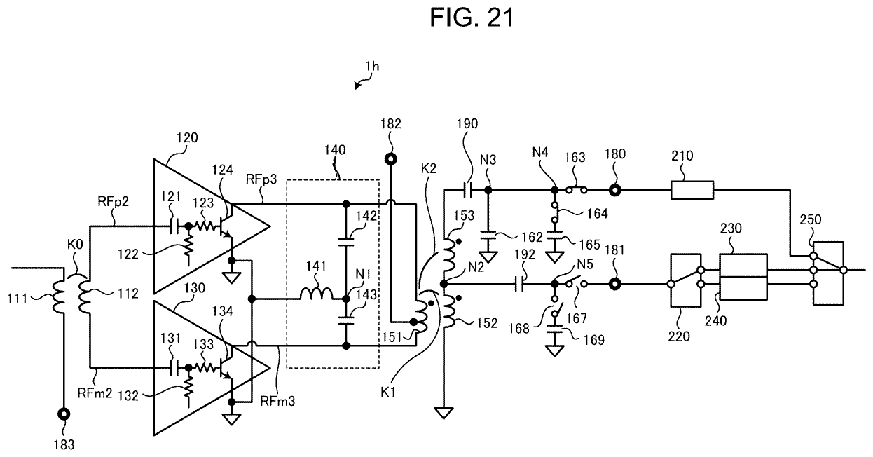

FIG. 21 is a diagram illustrating a power amplifying circuit 1h according to the ninth embodiment. Compared with the power amplifying circuit 1e of the sixth embodiment, the power amplifying circuit 1h according to the ninth embodiment further includes a circuit that follows the output terminals 180 and 181.

Specifically, the output terminal 180 is connected to and followed by a filter 210. Further, the output terminal 181 is connected to and followed by a single pole multiple throw (SPMT) switch 220 and filters 230 and 240. Furthermore, the filter 210 and the filter 230, 240 are connected to and followed by a multiple pole single throw (MPST) switch 250.

A pass band of the filter 210 is set at a frequency band through which a signal included in the operating frequency of the 2G mode is allowed to pass. Pass bands of the filters 230 and 240 are each set at a frequency band through which a signal included in the operating frequency of the 5G mode is allowed to pass. For example, the pass band of the filter 230 is set at a frequency band through which a signal of 5G VLB is allowed to pass, and the pass band of the filter 240 is set at a frequency band through which a signal of 5G LB is allowed to pass.

The SPMT switch 220 switches between inputting the output of the output terminal 181 to the filter 230 and inputting the output of the output terminal 181 to the filter 240, depending on whether the operation mode of the power amplifying circuit 1g is 5G VLB or 5G LB.

The MPST switch 250 switches between outputting the output of the filter 210 and outputting the output of the filter 230 or the filter 240, depending on whether the operation mode of the power amplifying circuit 1g is the 2G mode or the 5G mode.

As described above, installing the circuit that follows the output terminals 180 and 181 facilitates the switching between the 2G mode and the 5G mode.

In the present disclosure, each transistor is a bipolar transistor. However, the present disclosure is not limited thereto. The bipolar transistor has the emitter that is the first terminal, the collector that is the second terminal, and the base that is the third terminal. One example of the bipolar transistor is a heterojunction bipolar transistor (HBT). However, the present disclosure is not limited to this example. Each transistor may alternatively be, for example, a field effect transistor (FET). In that case, the emitter may be replaced with the source, the collector may be replaced with the drain, and the base may be replaced with the gate. Accordingly, it can also be said that the first terminal described above is the emitter or the source, the second terminal described above is the collector or the drain, and the third terminal described above is the base or the gate. Each transistor may also be a multi-finger transistor in which a plurality of unit transistors (also referred to as fingers) are electrically connected in parallel to each other. The unit transistors each corresponds to a minimum configuration that constitutes a transistor.

With regard to the description of claims, the present disclosure can have the following aspects.

<1> A power amplifying circuit including a differential amplifier that includes a first amplifier and a second amplifier and output terminals that include a first output terminal and a second output terminal, the power amplifying circuit comprising: a first inductor; a second inductor that is mutually coupled with the first inductor; a third inductor that is mutually coupled with the first inductor, power for the differential amplifier being supplied to an intermediate point of the first inductor, one end portion of the second inductor being connected to one end portion of the third inductor; a first capacitor, one end portion of the first capacitor being connected to another end portion of the second inductor; a first switch that is provided between the first output terminal and a connecting point of the one end portion of the second inductor and the one end portion of the third inductor; a second switch that is provided between another end portion of the third inductor and the second output terminal; a third switch, one end portion of the third switch being connected between the third inductor and the second switch; and a second capacitor that is connected between another end portion of the third switch and a reference potential, wherein another end portion of the first capacitor is connected to the reference potential, and by controlling the first switch, the second switch, and the third switch to be on or off, a signal of a desired frequency is outputted from the first output terminal or the second output terminal.

<2> The power amplifying circuit according to <1>, wherein in a first mode, the first switch is on, the second switch is off, the third switch is off, and a signal of a first frequency is outputted from the first output terminal, in a second mode, the first switch is on, the second switch is off, the third switch is on, and a signal of a second frequency that is different from the first frequency is outputted from the first output terminal, and in a third mode, the first switch is off, the second switch is on, the third switch is off, and a signal of a third frequency that is included in the first frequency is outputted from the second output terminal.

<3> The power amplifying circuit according to <1> or <2>, further comprising a fourth inductor that is provided between the first switch and the connecting point of the one end portion of the second inductor and the one end portion of the third inductor, wherein the fourth inductor is mutually coupled with the second inductor, and a turning direction of a current flowing through the second inductor is opposite a turning direction of a current flowing through the fourth inductor.

<4> A power amplifying circuit including a differential amplifier that includes a first amplifier and a second amplifier and output terminals that include a first output terminal and a second output terminal, the power amplifying circuit comprising: a first inductor; a second inductor that is mutually coupled with the first inductor; a third inductor that is mutually coupled with the first inductor, power for the differential amplifier being supplied to an intermediate point of the first inductor, one end portion of the second inductor being connected to one end portion of the third inductor; a first capacitor, one end portion of the first capacitor being connected to another end portion of the second inductor; a first switch that is provided between the first output terminal and a connecting point of the one end portion of the second inductor and the one end portion of the third inductor; a second switch that is provided between another end portion of the third inductor and the second output terminal; and a fifth inductor, one end portion of the fifth inductor being connected to a connecting point of the second inductor and the first capacitor, wherein another end portion of the first capacitor is connected to a reference potential, another end portion of the fifth inductor is connected to the reference potential, the fifth inductor is mutually coupled with the first inductor, a turning direction of a current flowing through the first inductor is opposite a turning direction of a current flowing through the fifth inductor, and by controlling the first switch and the second switch to be on or off, a signal of a desired frequency is outputted from the first output terminal or the second output terminal.

<5> The power amplifying circuit according to any one of <1> to <4>, further comprising a harmonic processing circuit that is connected in parallel to the first inductor in between an output port of the first amplifier and an output port of the second amplifier.

<6> The power amplifying circuit according to <5>, wherein the harmonic processing circuit includes a third capacitor, one end portion of the third capacitor being connected to the output port of the first amplifier, a fourth capacitor, one end portion of the fourth capacitor being connected to the output port of the second amplifier, another end portion of the third capacitor being connected to another end portion of the fourth capacitor, and a sixth inductor, one end portion of the sixth inductor being connected to a connecting point of the another end portion of the third capacitor and the another end portion of the fourth capacitor, another end portion of the sixth inductor being connected to the reference potential.

<7> The power amplifying circuit according to <5>, wherein the harmonic processing circuit includes a third capacitor, one end portion of the third capacitor being connected to the output port of the first amplifier, a fourth capacitor, one end portion of the fourth capacitor being connected to the output port of the second amplifier, another end portion of the third capacitor being connected to another end portion of the fourth capacitor, and a microstrip line, one end portion of the microstrip line being connected to a connecting point of the another end portion of the third capacitor and the another end portion of the fourth capacitor, another end portion of the microstrip line being connected to the reference potential.

<8> The power amplifying circuit according to any one of <1> to <7>, further comprising: a preamplifier that is provided in a stage that precedes the differential amplifier; and an inter-stage matching circuit that is provided between the preamplifier and the differential amplifier, wherein the inter-stage matching circuit includes a seventh inductor, one end portion of the seventh inductor being connected to an output port of the preamplifier, an eighth inductor that is mutually coupled with the seventh inductor, and a third capacitor that is connected in parallel to the eighth inductor, the first amplifier includes a first transistor whose emitter or source is connected to the reference potential and whose collector or drain is connected to one end portion of the first inductor, a signal at one end portion of the eighth inductor being inputted to a base or gate of the first transistor, and the second amplifier includes a second transistor whose emitter or source is connected to the reference potential and whose collector or drain is connected to another end portion of the first inductor, a signal at another end portion of the eighth inductor being inputted to a base or gate of the second transistor.

<9> A power amplifying circuit including a differential amplifier that includes a first amplifier and a second amplifier and output terminals that include a first output terminal and a second output terminal, the power amplifying circuit comprising: a first inductor; a second inductor that is mutually coupled with the first inductor; a third inductor that is mutually coupled with the first inductor, power for the differential amplifier being supplied to an intermediate point of the first inductor, one end portion of the second inductor being connected to one end portion of the third inductor; a first switch that is provided between the first output terminal and a connecting point of the one end portion of the second inductor and the one end portion of the third inductor; a second switch that is provided between another end portion of the third inductor and the second output terminal; a second capacitor, one end portion of the second capacitor being connected between the third inductor and the second switch, another end portion of the second capacitor being connected to a reference potential; a fourth capacitor that is provided between the another end portion of the third inductor and the one end portion of the second capacitor; and a fifth capacitor that is provided between the first switch and the connecting point of the one end portion of the second inductor and the one end portion of the third inductor, wherein another end portion of the second inductor is connected to the reference potential, and by controlling the first switch and the second switch to be on or off, a signal of a desired frequency is outputted from the first output terminal or the second output terminal.

<10> The power amplifying circuit according to <9>,

wherein in a first mode, the first switch is on, the second switch is off, and a signal of a first frequency is outputted from the first output terminal, in a second mode, the first switch is on, the second switch is off, and a signal of a second frequency that is different from the first frequency is outputted from the first output terminal, and in a third mode, the first switch is off, the second switch is on, and a signal of a third frequency that is included in the first frequency is outputted from the second output terminal.

<11> The power amplifying circuit according to <10>, further comprising a series circuit and a ninth inductor that are connected in parallel to the first inductor, wherein the series circuit includes a sixth capacitor and a tenth inductor that is connected in series to the sixth capacitor, and the series circuit is connected in series to the ninth inductor.

<12> The power amplifying circuit according to <2>,further comprising a series circuit and a ninth inductor that are connected in parallel to the first inductor, wherein the series circuit includes a sixth capacitor and a tenth inductor that is connected in series to the sixth capacitor, and the series circuit is connected in series to the ninth inductor.

<13> The power amplifying circuit according to <12>, wherein a resonant frequency of the series circuit is a center frequency of a frequency band that includes the first frequency and the second frequency.

1, 1a, 1b, 1c, 1d Power amplifying circuit

61c, 61f, 61g Microstrip line

100, 120, 130 Amplifier

110 Inter-stage matching circuit

140, 140a Harmonic processing circuit

101, 113, 114, 121, 131, 142, 143, 144, 154, 162, 165, 169 Capacitor

102, 122, 123, 132, 133 Resistor

104, 124, 131, 134 Transistor

111, 112, 141, 145, 146, 151, 152, 153, 155, 166 Inductor

161, 163, 164, 167, 168 Switch

180, 181 Output terminal

210, 230, 240 Filter

220 SPMT Switch

250 MPST Switch

1. A power amplifying circuit comprising a differential amplifier that comprises a first amplifier, a second amplifier, a first output terminal, and a second output terminal, the power amplifying circuit comprising:
a first inductor;
a second inductor that is mutually coupled with the first inductor;
a third inductor that is mutually coupled with the first inductor, power for the differential amplifier being supplied to an intermediate point of the first inductor, a first end portion of the second inductor being connected to a first end portion of the third inductor;
a first capacitor, a first end portion of the first capacitor being connected to a second end portion of the second inductor;
a first switch that is between the first output terminal and a connection point of the first end portion of the second inductor and the first end portion of the third inductor;
a second switch that is between a second end portion of the third inductor and the second output terminal;
a third switch, a first end portion of the third switch being connected between the third inductor and the second switch; and
a second capacitor that is connected between a second end portion of the third switch and a reference potential,
wherein a second end portion of the first capacitor is connected to the reference potential, and
wherein by controlling the first switch, the second switch, and the third switch to be in an on state or an off state, a signal having a desired frequency is output from the first output terminal or the second output terminal.

2. The power amplifying circuit according to claim 1,
wherein in a first mode, the first switch is on, the second switch is off, the third switch is off, and a signal having a first frequency is output from the first output terminal,
in a second mode, the first switch is on, the second switch is off, the third switch is on, and a signal having a second frequency that is different from the first frequency is output from the first output terminal, and
in a third mode, the first switch is off, the second switch is on, the third switch is off, and a signal having a third frequency that is included in the first frequency is output from the second output terminal.

3. The power amplifying circuit according to claim 1, further comprising:
a fourth inductor that is between the first switch and the connection point of the first end portion of the second inductor and the first end portion of the third inductor,
wherein the fourth inductor is mutually coupled with the second inductor, and
wherein a turning direction of a current flowing through the second inductor is opposite a turning direction of a current flowing through the fourth inductor.

4. A power amplifying circuit comprising a differential amplifier that comprises a first amplifier, a second amplifier, a first output terminal, and a second output terminal, the power amplifying circuit comprising:
a first inductor;
a second inductor that is mutually coupled with the first inductor;
a third inductor that is mutually coupled with the first inductor, power for the differential amplifier being supplied to an intermediate point of the first inductor, a first end portion of the second inductor being connected to a first end portion of the third inductor;
a first capacitor, a first end portion of the first capacitor being connected to a second end portion of the second inductor;
a first switch that is between the first output terminal and a connection point of the first end portion of the second inductor and the first end portion of the third inductor;
a second switch that is between a second end portion of the third inductor and the second output terminal; and
a fifth inductor, a first end portion of the fifth inductor being connected to a connection point of the second inductor and the first capacitor,
wherein a second end portion of the first capacitor is connected to a reference potential,
wherein a second end portion of the fifth inductor is connected to the reference potential, wherein the fifth inductor is mutually coupled with the first inductor,
wherein a turning direction of a current flowing through the first inductor is opposite a turning direction of a current flowing through the fifth inductor, and
wherein by controlling the first switch and the second switch to be on or off, a signal having a desired frequency is output from the first output terminal or the second output terminal.

5. The power amplifying circuit according to claim 1, further comprising:
a harmonic processing circuit that is connected in parallel to the first inductor between an output port of the first amplifier and an output port of the second amplifier.

6. The power amplifying circuit according to claim 4, further comprising:
a harmonic processing circuit that is connected in parallel to the first inductor between an output port of the first amplifier and an output port of the second amplifier.

7. The power amplifying circuit according to claim 5, wherein the harmonic processing circuit comprises:
a third capacitor, a first end portion of the third capacitor being connected to the output port of the first amplifier,
a fourth capacitor, a first end portion of the fourth capacitor being connected to the output port of the second amplifier, a second end portion of the third capacitor being connected to a second end portion of the fourth capacitor, and
a sixth inductor, a first end portion of the sixth inductor being connected to a connection point of the second end portion of the third capacitor and the second end portion of the fourth capacitor, a second end portion of the sixth inductor being connected to the reference potential.

8. The power amplifying circuit according to claim 6, wherein the harmonic processing circuit comprises:
a third capacitor, a first end portion of the third capacitor being connected to the output port of the first amplifier,
a fourth capacitor, a first end portion of the fourth capacitor being connected to the output port of the second amplifier, a second end portion of the third capacitor being connected to a second end portion of the fourth capacitor, and
a sixth inductor, a first end portion of the sixth inductor being connected to a connection point of the second end portion of the third capacitor and the second end portion of the fourth capacitor, a second end portion of the sixth inductor being connected to the reference potential.

9. The power amplifying circuit according to claim 5, wherein the harmonic processing circuit comprises:
a third capacitor, a first end portion of the third capacitor being connected to the output port of the first amplifier,
a fourth capacitor, a first end portion of the fourth capacitor being connected to the output port of the second amplifier, a second end portion of the third capacitor being connected to a second end portion of the fourth capacitor, and
a microstrip line, a first end portion of the microstrip line being connected to a connection point of the second end portion of the third capacitor and the second end portion of the fourth capacitor, a second end portion of the microstrip line being connected to the reference potential.

10. The power amplifying circuit according to claim 6, wherein the harmonic processing circuit comprises:
a third capacitor, a first end portion of the third capacitor being connected to the output port of the first amplifier,
a fourth capacitor, a first end portion of the fourth capacitor being connected to the output port of the second amplifier, a second end portion of the third capacitor being connected to a second end portion of the fourth capacitor, and
a microstrip line, a first end portion of the microstrip line being connected to a connection point of the second end portion of the third capacitor and the second end portion of the fourth capacitor, a second end portion of the microstrip line being connected to the reference potential.

11. The power amplifying circuit according to claim 1, further comprising:
a preamplifier that is in a stage that precedes the differential amplifier; and
an inter-stage matching circuit that is between the preamplifier and the differential amplifier,
wherein the inter-stage matching circuit comprises:
a seventh inductor, a first end portion of the seventh inductor being connected to an output port of the preamplifier,
an eighth inductor that is mutually coupled with the seventh inductor, and
a third capacitor that is connected in parallel to the eighth inductor,
wherein the first amplifier comprises:
a first transistor whose emitter or source is connected to the reference potential and whose collector or drain is connected to a first end portion of the first inductor, a signal at a first end portion of the eighth inductor being input to a base or gate of the first transistor, and
wherein the second amplifier comprises:
a second transistor whose emitter or source is connected to the reference potential and whose collector or drain is connected to a second end portion of the first inductor, a signal at a second end portion of the eighth inductor being input to a base or gate of the second transistor.

12. The power amplifying circuit according to claim 4, further comprising:
a preamplifier that is in a stage that precedes the differential amplifier; and
an inter-stage matching circuit that is between the preamplifier and the differential amplifier,
wherein the inter-stage matching circuit comprises:
a seventh inductor, a first end portion of the seventh inductor being connected to an output port of the preamplifier,
an eighth inductor that is mutually coupled with the seventh inductor, and
a third capacitor that is connected in parallel to the eighth inductor,
wherein the first amplifier comprises:
a first transistor whose emitter or source is connected to the reference potential and whose collector or drain is connected to a first end portion of the first inductor, a signal at a first end portion of the eighth inductor being input to a base or gate of the first transistor, and
wherein the second amplifier comprises:
a second transistor whose emitter or source is connected to the reference potential and whose collector or drain is connected to a second end portion of the first inductor, a signal at a second end portion of the eighth inductor being input to a base or gate of the second transistor.

13. A power amplifying circuit comprising a differential amplifier that comprises a first amplifier, a second amplifier, a first output terminal, and a second output terminal, the power amplifying circuit comprising:
a first inductor;
a second inductor that is mutually coupled with the first inductor;
a third inductor that is mutually coupled with the first inductor, power for the differential amplifier being supplied to an intermediate point of the first inductor, a first end portion of the second inductor being connected to a first end portion of the third inductor;
a first switch that is between the first output terminal and a connection point of the first end portion of the second inductor and the first end portion of the third inductor;
a second switch that is between a second end portion of the third inductor and the second output terminal;
a second capacitor, a first end portion of the second capacitor being connected between the third inductor and the second switch, a second end portion of the second capacitor being connected to a reference potential;
a fourth capacitor that is between the second end portion of the third inductor and the first end portion of the second capacitor; and
a fifth capacitor that is between the first switch and the connection point of the first end portion of the second inductor and the first end portion of the third inductor,
wherein a second end portion of the second inductor is connected to the reference potential, and
wherein by controlling the first switch and the second switch to be on or off, a signal having a desired frequency is output from the first output terminal or the second output terminal.

14. The power amplifying circuit according to claim 13,
wherein in a first mode, the first switch is on, the second switch is off, and a signal having a first frequency is output from the first output terminal,
in a second mode, the first switch is on, the second switch is off, and a signal of a second frequency that is different from the first frequency is output from the first output terminal, and
in a third mode, the first switch is off, the second switch is on, and a signal having a third frequency that is included in the first frequency is output from the second output terminal.

15. The power amplifying circuit according to claim 14, further comprising:
a series circuit and a ninth inductor that are connected in parallel to the first inductor,
wherein the series circuit comprises a sixth capacitor, and a tenth inductor that is connected in series to the sixth capacitor, and
wherein the series circuit is connected in series to the ninth inductor.

16. The power amplifying circuit according to claim 2, further comprising:
a series circuit and a ninth inductor that are connected in parallel to the first inductor,
wherein the series circuit comprises a sixth capacitor, and a tenth inductor that is connected in series to the sixth capacitor, and
wherein the series circuit is connected in series to the ninth inductor.

17. The power amplifying circuit according to claim 16, wherein a resonant frequency of the series circuit is a center frequency of a frequency band that includes the first frequency and the second frequency.
